(19) United States
(12) Patent Application Publication
(10) Pub. No.: US 2026/0212945 A1
(43) Pub. Date: Jul. 23, 2026

(54) MEMORY ERROR DETECTION AND TRACKING

(71) Applicant: QUALCOMM Incorporated, San Diego, CA (US)

(72) Inventors: Ishwarya Arumugam, Coimbatore-Pollachi (IN); Sateeshkumar Injarapu, Bangalore (IN); Manish Kumar Saxena, Bangalore (IN); Amit Duggal, Bangalore (IN); Nitin Jaiswal, Bangalore (IN)

(21) Appl. No.: 19/033,145

(22) Filed: Jan. 21, 2025

(51) Int. Cl. G11C 29/44

(52) U.S. Cl. CPC G11C 29/44

(57) ABSTRACT

This disclosure provides systems, methods, and devices for memory systems that support detecting and tracking a quantity of errors in memory using a counter and indicating the detection and quantity of errors using an interrupt flag. In a first aspect, a method includes, at a hardware of a memory system detecting one or more errors at a memory. The method includes counting a quantity of the one or more errors until the quantity is equal to or greater than a threshold quantity of errors. The method includes recording the quantity of errors and an error type in an error log. The method includes transmitting an indication that the quantity of errors of the memory is equal to or greater than the threshold. Other aspects and features are also claimed and described.

### TECHNICAL FIELD

Aspects of the present disclosure relate generally to an apparatus and method for detecting and tracking errors (e.g., faults) in a memory. Some aspects may, more particularly, relate to an apparatus and method detecting and tracking a quantity of errors in memory using a counter and indicating the detection and quantity of errors using an interrupt flag.

### INTRODUCTION

As the value and use of information continues to increase, individuals and businesses seek additional ways to process and store information. In addition, the use of information in various locations and desired portability of information is increasing. For this reason, users are increasingly turning towards the use of portable electronic devices, such as mobile phones, digital cameras, laptop computers and the like. Portable electronic devices generally employ a memory system using a memory device for storing data. A memory system may be used as a main memory or an auxiliary memory of a portable electronic device.

The memory device of the memory system may include one kind or a combination of kinds of storage. For example, magnetic-based memory systems, such as hard disk drives (HDDs), store data by encoding data as a combination of small magnets. As another example, optical-based memory systems, such as digital versatile discs (DVDs) and Blu-ray media, store data by encoding data as physical bits that cause different reflections when illuminated by a light source. As a further example, electronic memory devices store data as collections of electrons that can be detected through voltage and/or current measurements.

Electronic memory devices can be advantageous in certain systems in that they may access data quickly and consume a small amount of power. Examples of an electronic memory device having these advantages include universal serial bus (USB) memory devices (sometimes referred to as “memory sticks”), a memory card (such as used in some cameras and gaming systems), and solid state drives (SSDs) (such as used in laptop computers). NAND flash memory is one kind of memory device that may be used in electronic memory devices. NAND flash memory is manufactured into memory cards or flash disks. Example memory cards include compact flash (CF) cards, multimedia cards (eMMCs), smart media (SM) cards, and secure digital (SD) cards.

A memory system may, in some cases, be integrated with or otherwise connected to a host device, such as an electronic device. For example, memory systems may be integrated with host devices in a system on chip (SoC). As one particular example, a flash memory system, which may be a universal flash storage (UFS) memory system, may be integrated into an electronic device, such as an access point (AP), station (STA), user equipment (UE), base station, modem, camera, automobile, or other system.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

Integrated circuits, which are used in a variety of electronic devices, may have many memories. In some cases, the memories may not operate as expected, resulting in errors. Errors in memory may be detected using an Error Correcting Code (ECC) and ECC fault signatures may be stored. An ECC fault signature may indicate an error type associated with an address of memory, for example, and the fault signature may be retrieved for processing by a software (e.g., system) associated with the integrated circuit. Often, the software may analyze the fault signature for each instance of an error type occurring at a memory address and mitigate or resolve for the error accordingly. That is, the software may resolve for one or more errors on a per-error and a per-address basis.

For example, an ECC associated with a memory may detect that an error has occurred at an address of a memory, such as a single bit error, and may store a corresponding fault signature for processing by the software. The software may retrieve the fault signature to identify the address associated with the error type and associate it with a memory. Subsequently, the ECC may detect another single-bit error and may store the corresponding fault signature. The software may retrieve the fault signature to identify the address associated with the error type, and in some cases, the software may check whether the address is associated with the same memory of the previously checked error (e.g., count errors for the memory based on the addresses). In some cases, the addresses may be associated with respective counters. The software may repeat the process of retrieving the fault signature per-error for subsequent error detections. Retrieving a fault signature for each error and processing each of the fault signatures on a per-error and per-address basis may result in latencies, which may further result in more significant errors at the memory.

Additionally, in some cases, if multiple errors occur at the memory (e.g., at a first address, a third address, etc.) and the software is processing other data, the software may identify the fault signature that was received last or when the software became available to process errors. That is, any previous fault signatures associated with a memory may be disregarded, resulting in an inaccurate count of the quantity of errors occurring at the memory. Inaccurate count of the quantity of errors may result in significant errors at the memory. For example, if the quantity of errors (e.g., single-bit errors) reaches a threshold quantity of errors for the memory, a subsequent error may be an uncorrectable error (e.g., multiple-bit error) that may result in a permanent error that causes the memory system to shut down. Inaccurate count of the quantity of errors may result in the software not performing remedial actions to prevent the uncorrectable error and memory system shutdown.

To efficiently and precisely detect errors prior to the software retrieving the error fault signature, a counter at a memory may be used to count error detections. The counter-based error detection and counting may occur at the hardware (e.g., instead of the software), such as at a graphical processing unit (GPU). In this manner, the software may process other data or perform other operations while the errors are detected and precisely counted at the hardware. For example, the counter may count the quantity of errors until the quantity reaches a threshold quantity of errors for the memory. When the quantity of errors reaches the threshold quantity of errors, the fault signature may be retrieved by the software for remedial actions. The fault signature may indicate the quantity of errors that occurred at the memory and the error type (e.g., rather than an address of a memory and the error type). Thus, latencies involved with per-error and per-address retrieval may be avoided.

In some examples, the hardware may provide an interrupt flag to the software that indicates that the error count at the respective memory has exceeded the threshold quantity of errors. The interrupt may be a trigger event that causes the software to retrieve the fault signature from hardware, for example, to identify the particular memory that has multiple errors (e.g., multiple errors reaching the threshold). The software may mitigate or perform remedial actions after identifying the particular memory with the multiple errors. The software may be available to perform other operations until the software receives the interrupt flag, interrupting the software for current operations to retrieve the fault signature. The errors counted may be single-bit errors. The single-bit errors reaching the threshold may be indicative of a possible multiple-bit error occurring subsequently, and the software may preemptively perform remedial actions or mitigate for the possible multiple-bit error that may result in a permanent error a memory system shutdown.

Accordingly, the counter-based hardware for detecting and counting errors for an associated memory may facilitate reduced latencies otherwise associated with multiple iterations of retrieving the fault signature for an error occurring at an address of a memory (e.g., retrieving on a per-error basis). Detecting the errors and counting the errors occurring at the memory in hardware may increase software availability to perform other operations until the quantity of errors reaches the threshold. Additionally, the counter that counts the quantity of errors for a memory may provide an accurate detection of the quantity of errors occurring at the memory since the software identifies an error when the software becomes available to perform an error analysis (e.g., missing previous errors that may have occurred while the software was occupied with other operations or processes).

In one aspect of the disclosure, an apparatus includes one or more memories storing processor-executable code. The apparatus includes one or more processors coupled with the one or more memories. The one or more processors may be individually or collectively operable to execute the code to cause the apparatus to detect one or more errors at a memory. The one or more processors may be individually or collectively further operable to execute the code to cause the apparatus to count a quantity of the one or more errors until the quantity is equal to or greater than a threshold quantity of errors. The one or more processors may be individually or collectively further operable to execute the code to cause the apparatus to record the quantity of errors and an error type in an error log. The one or more processors may be individually or collectively further operable to execute the code to cause the apparatus to transmit an indication of the quantity of errors of the memory being equal to or greater than the threshold.

In some examples, the apparatus may include a counter. The one or more processors may be individually or collectively further operable to execute the code to cause the apparatus to increment the counter based on a detection of an error of the one or more errors. In some examples, the one or more errors may be associated with one or more addresses of the memory. In some examples, the indication may include an interrupt flag. In some examples, to transmit the indication, the one or more processors may be individually or collectively further operable to execute the code to cause the apparatus to transmit the indication to a software of a memory system associated with the memory, and where the apparatus include a hardware associated with the memory.

In such examples, the hardware may include a graphical processing unit associated with the memory. In some examples, the indication that the quantity of errors is equal to or greater than the threshold may include a set of bits indicative of the error type. In some examples, the error type may be a single-bit error. In some examples, the indication that the quantity errors is equal to or greater than the threshold may indicate an expectation of a double-error detection error. In some examples, the apparatus includes a vehicle or may be associated with a vehicle, and the one or more processors may be individually or collectively further operable to execute the code to cause the apparatus to transmit a notification to discontinue use of vehicle based on the indication of the quantity of errors of the memory being equal to or greater than the threshold.

In some examples, to count a quantity of the one or more errors, the one or more processors may be individually or collectively further operable to execute the code to cause the apparatus to determine a total number of errors as the quantity of the one or more errors based on errors counted at a set of addresses of the memory.

In another aspect of the disclosure, a method for performing these operations by a processor by executing instructions stored in a memory coupled to the processor is also disclosed. In an additional aspect of the disclosure, a non-transitory computer-readable medium stores instructions that, when executed by a processor, cause the processor to perform these operations.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

FIG. 1 is a block diagram illustrating a data processing system including a memory system in accordance with an embodiment of the present invention.

FIG. 2 is a block diagram illustrating an example electronic device including the memory system according to one or more aspects of the disclosure.

FIG. 3 is a block diagram illustrating components for facilitating access to a flash memory device from a host device according to some embodiments of the disclosure.

FIG. 4 is a flow diagram illustrating the system for generating the error correction code fault signature according to some embodiments of the disclosure.

FIG. 5 is an example of an error log according to some embodiments of the disclosure.

FIG. 6 is an example illustrating usage of the detecting and tracking errors prior to processing according to some embodiments of the disclosure.

FIG. 7 is a flow diagram illustrating a method for generating the error correction code fault signature according to some embodiments of the disclosure.

FIG. 8 is a flow diagram illustrating a method for counting errors at a counter according to some embodiments of the disclosure.

FIG. 9 is flow chart illustrating a method for detecting and tracking errors by hardware of a memory system according to some embodiments of the disclosure.

FIG. 10 is a flow chart illustrating a method for resolving for errors by software of a memory system according to some embodiments of the disclosure.

FIG. 11 is a flow chart illustrating a method for resolving errors occurring at a memory using hardware and software according to some embodiments of the disclosure.

FIG. 12 is a block diagram illustrating details of an example wireless communication system according to one or more aspects.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

The present disclosure provides systems, apparatus, methods, and computer-readable media that support data processing, including techniques for storing, retrieving, and organizing data in a memory system. Aspects of this disclosure provide for operations and data structures used in those operations for detecting and tracking a quantity of errors in memory using a counter (e.g., in hardware) and indicating the detection and quantity of errors using an interrupt flag (e.g., to software) to facilitate remedial actions.

Integrated circuits, which are used in a variety of electronic devices, may have many memories. In some cases, the memories may not operate as expected, resulting in errors. Errors in memory may be detected using an Error Correcting Code (ECC) and ECC fault signatures may be stored. An ECC fault signature may indicate an error type associated with an address of memory, for example, and the fault signature may be retrieved for processing by a software (e.g., system) associated with the integrated circuit. Often, the software may analyze the fault signature for each instance of an error and mitigate or resolve for the error accordingly. That is, the software may resolve for one or more errors on a per-error and a per-address basis.

In particular, the ECC may detect errors and add bits to data being stored in memory to indicate errors. The bits may allow the software to detect and correct the errors. The errors may be single-bit errors and/or multiple-bit errors in the data. The single-bit error may be coded as a single error correction (SEC), which indicates that the software may identify and correct the single-bit error that occurred during data storage. The single-bit error occurs when one bit within a data packet is altered, either from 0 to 1 or 1 to 0. The multiple-bit error occurs when two or more bits within the data packet are altered (e.g., multiple errors within the same data packet). The multiple-bit error or double-bit error may be coded as a double error detection (DED), which indicates that the software may identify but not correct the error. A DED may result in the software resetting or shutdown the memory system.

Often, the software may analyze the fault signature for each instance of an error type occurring at a memory address and mitigate or resolve for the error accordingly. That is, the software may resolve for one or more errors on a per-error and a per-address basis. For example, an ECC associated with a memory may detect that an error has occurred at an address of the memory, such as a single-bit error, and may store a corresponding fault signature for processing by the software. The software may retrieve the fault signature to identify the address associated with the error type and associate it with a memory. Subsequently, the ECC may detect another single-bit error and may store the corresponding fault signature. The software may retrieve the fault signature to identify the address associated with the error type, and in some cases, the software may check whether the address is associated with the same memory of the previously checked error (e.g., count errors for the memory based on the addresses). In some cases, the addresses may be associated with respective counters. The software may repeat the process of retrieving the fault signature per-error for subsequent error detections. Retrieving a fault signature for each error and processing each of the fault signatures on a per-error and per-address basis may result in latencies, which may further result in more significant errors at the memory.

Additionally, in some cases, if multiple errors occur at the memory (e.g., at a first address, a third address, etc.) and the software is processing other data, the software may identify the fault signature that was received last or when the software became available to process errors. That is, any previous fault signatures associated with a memory may be disregarded, resulting in an inaccurate count of the quantity of errors occurring at the memory. For example, if the quantity of errors (e.g., single-bit errors, SECs) reaches a threshold quantity of errors for the memory, a subsequent error may be an uncorrectable error (e.g., multiple-bit error, DED) that may result in a permanent error that causes the memory system to shut down. Inaccurate count of the quantity of errors may result in the software not performing remedial actions to prevent the uncorrectable error and memory system shutdown. In some cases, the shutdown since the detected DED may not be a graceful shutdown.

As discussed herein, to efficiently and precisely detect errors prior to the software retrieving the error fault signature, a counter at a memory may be used to count error detections. The counter-based error detection and counting may occur at the hardware (e.g., instead of the software), such as at a graphical processing unit (GPU). In this manner, the software may process other data or perform other operations while the errors are detected and precisely counted at the hardware. For example, the counter may count the quantity of errors until the quantity reaches a threshold quantity of errors for the memory. When the quantity of errors reaches the threshold quantity of errors, the fault signature may be retrieved by the software for remedial actions. The fault signature may indicate the quantity of errors that occurred at the memory and the error type (e.g., rather than an address of a memory and the error type). Thus, latencies involved with per-error and per-address retrieval may be avoided.

In some examples, the hardware may provide an interrupt flag to the software that indicates that the error count at the respective memory has reached the threshold quantity of errors. The interrupt may be a trigger event that causes the software to retrieve the fault signature from the hardware, for example, to identify the particular memory that has multiple errors. The software may mitigate or perform remedial actions after identifying the memory with the multiple errors. The software may be available to perform other operations until the software receives the interrupt flag, interrupting the software for current operations to retrieve the fault signature. The errors counted may be SECs. The SECs reaching the threshold may be indicative of a possible DED occurring subsequently, and the software may preemptively perform remedial actions or mitigate for the possible DED.

Particular implementations of the subject matter described in this disclosure may be implemented to realize one or more of the following potential advantages or benefits. In some aspects, the present disclosure provides techniques for improved performance of a memory system. For example, the counter-based hardware for detecting and counting errors for an associated memory may facilitate reduced latencies otherwise associated with multiple iterations of retrieving the fault signature for an error occurring at an address of a memory (e.g., retrieving on a per-error basis). Detecting the errors and counting the errors occurring at the memory in hardware may increase software availability to perform other operations until the quantity of errors reaches the threshold. Additionally, the counter that counts the quantity of errors for a memory may provide an accurate detection of the quantity of errors occurring at the memory since the software identifies an error when the software becomes available to perform an error analysis (e.g., missing previous errors that may have occurred while the software was occupied with other operations or processes).

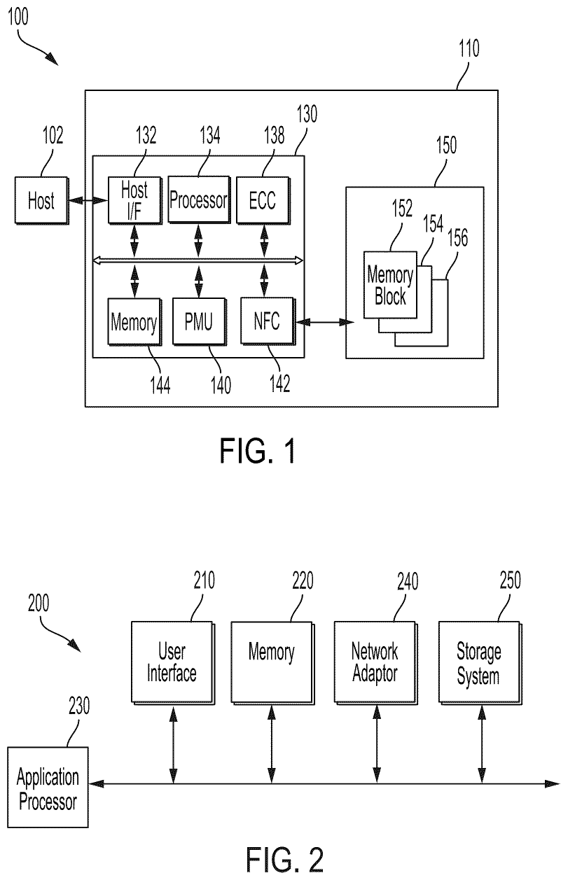

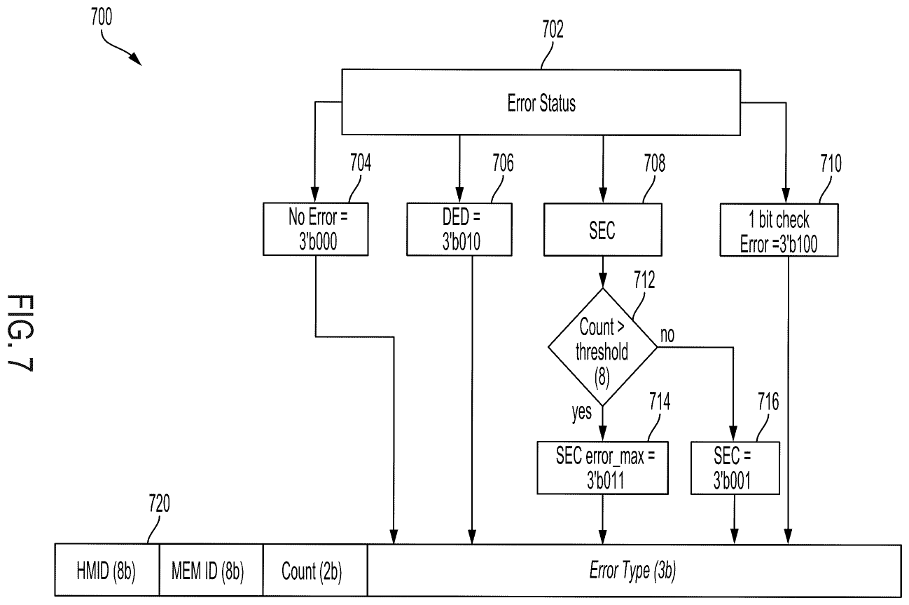

Memory may be used in a computing system organized as illustrated in FIG. 1. FIG. 1 illustrates a memory processing system 100, such as may be included in a mobile computing device, according to one or more aspects of the disclosure. A memory system 110 may couple to a host device 102 through one or more channels. For example, the host device 102 and memory system 110 may be coupled through a serial interface including a single channel for the transport of data or a parallel interface including two or more channels for the transport of data. In some aspects, control data may be transferred through the same channel(s) as the data or the control data may be transferred through additional channels. The host device 102 may be, for example, a portable electronic device such as a mobile phone, an MP3 player, a laptop computer, or a non-portable electronic device such as a desktop computer, a game player, a television (TV), a media player, or a projector. As another example, the host device 102 may be an automotive computer system. In some examples, the memory system 110 may be included in the host device 102. Thus, the memory processing system 100 may be any of the example host devices described herein including the memory system 110. Additional example host devices are illustrated and described with reference to FIG. 6.

The memory system 110 may execute operations in response to commands (e.g., a request) from the host device 102. For example, the memory system 110 may store data provided by the host device 102 and the memory system 110 may also provide stored data to the host device 102. The memory system 110 may be used as a main memory, short-term memory, or long-term memory by the host device 102. As one example of main memory, the host device 102 may use the memory system 110 to supplement or replace a system memory by using the memory system 110 to store temporary data such as data relating to operating systems and/or threads executing in the operation system. As one example of short-term memory, the host device 102 may use the memory system 110 to store a page file for an operating system. As one example of long-term memory, the host device 102 may use the memory system 110 to store user files (e.g., documents, videos, pictures) and/or application files (e.g., word processing executable, gaming application).

The memory system 110 may be implemented with any one of various storage devices, according to the protocol of a host interface for the one or more channels coupling the memory system 110 to the host device 102. The memory system 110 may be implemented with any one of various storage devices, such as a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, or a memory stick.

The memory system 110 may include a memory module 150 and a controller 130 coupled to the memory module 150 through one or more channels. The memory module 150 may store and retrieve data in physical memory blocks 152, 154, and 156 under control of the controller 130, which may execute commands received from the host device 102. The controller 130 is configured to control data exchange between the memory module 150 and the host device 102. The storage components, such as physical memory blocks 152, 154, and 156 in the memory module 150 may be implemented as volatile memory device, such as, a dynamic random access memory (DRAM) and a static random access memory (SRAM), or a non-volatile memory device, such as a read only memory (ROM), a programmable ROM (PROM), an erasable programmable ROM (EPROM), an electrically erasable programmable ROM (EEPROM), a ferroelectric random access memory (FRAM), a phase-change RAM (PRAM), a magnetoresistive RAM (MRAM), a resistive RAM (SCRAM), or a NAND flash memory.

The controller 130 and the memory module 150 may be formed as integrated circuits on one or more semiconductor dies (or other substrate). In some aspects, the controller 130 and the memory module 150 may be integrated into one chip. In some aspects, the memory module 150 may include one or more chips coupled in series or parallel with each other and coupled to the controller 130, which is on a separate chip. In some aspects, the memory module 150 and controller 130 chips are integrated in a single package, such as in a package on package (POP) system. In some aspects, the memory system 110 is integrated on a single chip with one or more or all of the components (e.g., application processor, system memory, digital signal processor, modem, graphics processor unit, memory interface, input/output interface, network adaptor) of the host device 102, such as in a system on chip (SoC). The controller 130 and the memory module 150 may be integrated into one semiconductor device to form a memory card, such as, for example, a Personal Computer Memory Card International Association (PCMCIA) card, a compact flash (CF) card, a smart media card (SMC), a memory stick, a multimedia card (MMC), an RS-MMC, a micro-MMC, a secure digital (SD) card, a mini-SD, a micro-SD, an SDHC, and a universal flash storage (UFS) device.

The controller 130 of the memory system 110 may control the memory module 150 in response to commands from the host device 102. The controller 130 may execute read commands to provide the data from the memory module 150 to the host device 102. The controller 130 may execute write commands to store data provided from the host device 102 into the memory module 150. The controller 130 may execute other commands to manage data in the memory module 150, such as program and erase commands. The controller 130 may also execute other commands to manage control of the memory system 110, such as setting configuration registers of the memory system 110. By executing commands in accordance with the configuration specified in the configuration registers, the controller 130 may control operations of the memory module 150, such as read, write, program, and erase operations.

The controller 130 may include several components configured for performing the received commands. For example, the controller 130 may include a host interface (I/F) unit 132, a processor 134, an error correction code (ECC) unit 138, a power management unit (PMU) 140, a NAND flash controller (NFC) 142, and/or a memory 144. The power management unit (PMU) 140 may provide and manage power for components within the controller 130 and/or the memory module 150.

The host interface unit 132 may process commands and data provided from the host device 102, and may communicate with the host device 102, through at least one of various interface protocols such as universal serial bus (USB), multimedia card (MMC), peripheral component interconnect express (PCI-e), serial attached SCSI (SAS), serial advanced technology attachment (SATA), parallel advanced technology attachment (PATA), small computer system interface (SCSI), enhanced small disk interface (ESDI), and integrated drive electronics (IDE). For example, the host interface unit 132 may be a parallel interface such as an MMC interface, or a serial interface such as an ultra-high speed class 1 (UHS-I)/UHS class 2 (UHS-II) or a universal flash storage (UFS) interface.

The ECC unit 138 may detect and correct errors in the data read from the memory module 150 during the read operation. The ECC unit 138 may not correct error bits when the number of the error bits is greater than a threshold number of correctable error bits, which may result in the ECC unit 138 outputting an error correction fail signal indicating failure in correcting the error bits. In some aspects, no ECC unit 138 may be provided or the ECC unit 138 may be configurable to be active for some or all of the memory module 150. The ECC unit 138 may perform an error correction operation using a coded modulation such as a low-density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), or a Block coded modulation (BCM).

The NFC 142 provides an interface between the controller 130 and the memory module 150 to allow the controller 130 to control the memory module 150 in response to a commands received from the host device 102. The NFC 142 may generate control signals for the memory module 150, such as signals for rowlines and bitlines, and process data under the control of the processor 134. Although NFC 142 is described as a NAND flash controller, other controllers may perform similar function for other memory types used as memory module 150.

The memory 144 may serve as a working memory of the memory system 110 and the controller 130. The memory 144 may store data for driving the memory system 110 and the controller 130. When the controller 130 controls an operation of the memory module 150 such as, for example, a read, write, program or erase operation, the memory 144 may store data which are used by the controller 130 and the memory module 150 for the operation. The memory 144 may be implemented with a volatile memory such as, for example, a static random access memory (SRAM) or a dynamic random access memory (DRAM). In some aspects, the memory 144 may store address mappings, a program memory, a data memory, a write buffer, a read buffer, a map buffer, and the like.

The processor 134 may control the general operations of the memory system 110, and a write operation or a read operation for the memory module 150, in response to a write request or a read request received from the host device 102, respectively. For example, the processor 134 may execute firmware, which may be referred to as a flash translation layer (FTL), to control the general operations of the memory system 110. The processor 134 may be implemented, for example, with a microprocessor or a central processing unit (CPU), or an application-specific integrated circuit (ASIC).

FIG. 2 is a block diagram illustrating an example electronic device including the memory processing system 100 according to one or more aspects of the disclosure. The electronic device 200 may include a user interface 210, a memory 220, an application processor 230, a network adaptor 240, and a storage system 250 (which may be one embodiment of the memory processing system 100 of FIG. 1). The application processor 230 may be coupled to the other components through a bus, such as a peripheral component interface (PCI) bus, including a PCI express (PCIe) bus.

The application processor 230 may execute computer program code, including applications, drivers, and operating systems, to coordinate performing of tasks by components included in the electronic device 200. For example, the application processor 230 may execute a storage driver for accessing the storage system 250. The application processor 230 may be part of a system-on-chip (SoC) that includes one or more other components shown in electronic device 200.

The memory 220 may operate as a main memory, a working memory, a buffer memory or a cache memory of the electronic device 200. The memory 220 may include a volatile random access memory such as a dynamic random access memory (DRAM), a synchronous dynamic random access memory (SDRAM), a double data rate (DDR) SDRAM, a DDR2 SDRAM, a DDR3 SDRAM, a low power double data rate (LPDDR) SDRAM, an LPDDR2 SDRAM, an LPDDR3 SDRAM, an LPDDR4 SDRAM, an LPDDR5 SDRAM, or an LPDDR6 SDRAM, or a nonvolatile random access memory such as a phase change random access memory (PRAM), a resistive random access memory (ReRAM), a magnetic random access memory (MRAM) and a ferroelectric random access memory (FRAM). In some aspects, the application processor 230 and the memory 220 may be combined using a package-on-package (POP).

The network adaptor 240 may communicate with external devices. For example, the network adaptor 240 may support wired communications and/or various wireless communications such as code division multiple access (CDMA), global system for mobile communication (GSM), wideband CDMA (WCDMA), CDMA-2000, time division multiple access (TDMA), long term evolution (LTE), worldwide interoperability for microwave access (WiMAX), wireless local area network (WLAN), ultra-wideband (UWB), Bluetooth, wireless display (Wi-Di), and so on, and may thereby communicate with wired and/or wireless electronic appliances, for example, a mobile electronic appliance.

The storage system 250 may store data, for example, data received from the application processor 230, and transmit data stored therein, to the application processor 230. The storage system 250 may be a non-volatile semiconductor memory device, such as a phase-change RAM (PRAM), a magnetic RAM (MRAM), a resistive RAM (ReRAM), a NAND flash memory, a NOR flash memory, or a 3-dimensional (3-D) NAND flash memory. The storage system 250 may be a removable storage medium, such as a memory card or an external drive. For example, the storage system 250 may correspond to the memory system 110 described above with reference to FIG. 1 and may be a SSD, eMMC, UFS, or other flash memory system.

The user interface 210 provide one or more graphical user interfaces (GUIs) for inputting data or commands to the application processor 230 or for outputting data to an external device. For example, the user interface 210 may include user input interfaces, such as a virtual keyboard, a touch screen, a camera, a microphone, a gyroscope sensor, or a vibration sensor, and user output interfaces, such as a liquid crystal display (LCD), an organic light emitting diode (OLED) display device, an active matrix OLED (AMOLED) display device, a light emitting diode (LED), a speaker, or a haptic motor.

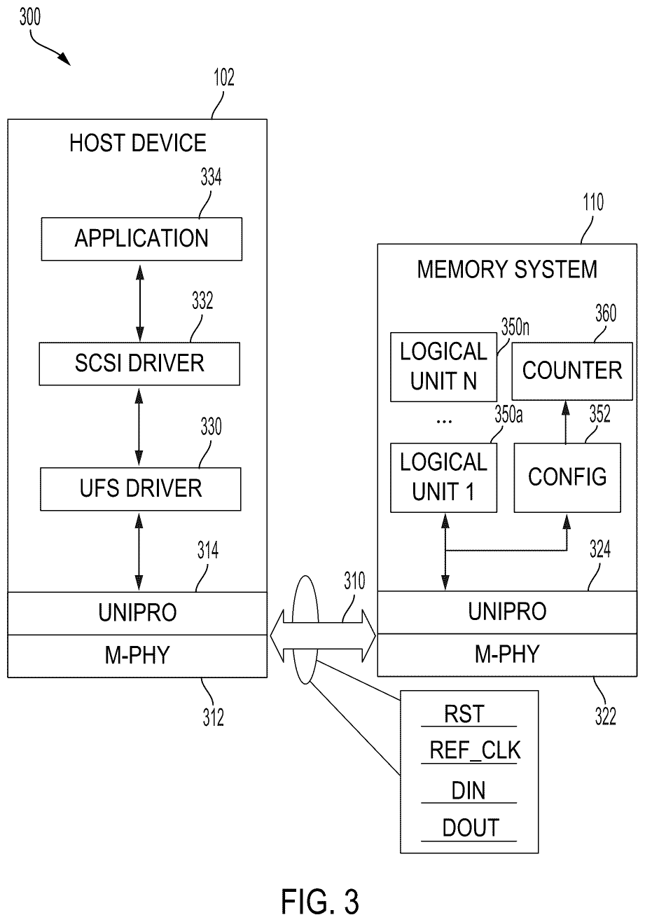

FIG. 3 is a block diagram illustrating components for facilitating access to a flash memory system from a host device according to some embodiments of the disclosure. The host device 102 accesses the memory system 110 through a memory interface 310. The memory interface 310 may, for example, be a physical interface (PHY) connecting the host device 102 to the memory system 110. The host device 102 may include physical layer access block 312, which is configured to generate signals for output to the memory interface 310 and process signals received through the memory interface 310. The memory system 110 includes a similarly-configured physical layer access block 322 for communicating on the memory interface 310. One example physical layer specification for communicating on the memory interface 310 is the MIPI M-PHY™ physical layer specification.

The host device 102 also includes a data link layer block 314 configured to format frames of data for transmission on the memory interface 310. The frames may be provided to the physical layer access block 312 for transmission. The data link layer block 314 may receive frames from the physical layer access block 312 and decode frames of data received on the memory interface 310. The memory system 110 includes a similarly-configured data link layer block 324 for processing frames transmitted on or received on the memory interface 310 by the physical layer access block 322. One example data link protocol for communicating on a MIPI M-PHY™ physical link is the MIPI UNIPRO™ specification.

The memory system 110 includes N logical units 350a-n comprising logical memory blocks for storing information including user data (e.g., user documents, application data) and configuration data (e.g., information regarding operation of the memory system 110). The logical units 350a-n may map to portions of the physical memory blocks 152, 154, and 156. Some of the logical units 350a-n or portions of the logical units 350a-n may be configured with write protection, with boot capability, as a specific memory type (e.g., default, system code, non-persistent, enhanced), with priority access, or with replay protection as a replay protected memory block (RPMB). The physical layer access block 322 and the data link layer block 324 perform operations of a memory controller for the memory system 110 for storing and retrieving data in logical units 350a-n.

The memory system 110 also includes configuration structures 352. The configuration structures 352 may include information such as configuration descriptors for boot enable (bBootEnable), initial power mode (bInitPowerMode), RPMB active (bRPMBRegionEnable), and/or RPMB region sizes (bRPMBRegion1Size, bRPMBRegion2Size, bRPMBRegion3Size). Such configuration structures and/or parameters may, for example, be configuration structures and/or parameters identified by the UFS standard. In some examples, the memory system 110 may also include counters 360 associated with respective memories. A counter 360 may count the quantity of errors occurring at a memory until the quantity of errors reaches a threshold quantity of errors. The threshold may be set and reset (e.g., dynamic) based on an application associated with the memory. As discussed herein, an interrupt flag may be provided to the software of the memory system 110, causing the software to retrieve the fault signature associated with the memory. The fault signature may indicate a set of bits that are indicative of the error type (e.g., SECs reaching or exceeding the threshold) and the quantity of errors.

The host device 102 may be configured to execute one or more applications 334, such as user applications executed by an operating system under the control of a user to receive user input and provide information stored in the memory system 110 to the user. The host device 102 may include several components for interfacing the application 334 to the memory system 110 through the memory interface 310. For example, a SCSI driver 332 and a UFS driver 330 may interface the application 334 to a host memory controller that includes the data link layer block 314 and the physical layer access block 312. The SCSI driver 332 may execute at an application layer for handling transactions requested by the application 334 with the memory system 110. The UFS driver 330 may execute at a transport layer and manage operation of the data link layer block 314, such as to operate the memory interface 310 at one of a plurality of modes of operations. The modes of operations may include two or more gear settings, such as one or more PWM-GEAR settings and four or more HS-GEAR settings specifying one bitrate from 182 MBps, 364 MBps, 728 MBps, and 1457 MBps.

The memory interface 310 may include one or more lines including a reset RST line, a reference clock REF_CLK line, a data-in DIN line (for data transmissions from the host device 102 to the memory system 110), and a data-out DOUT line (for data transmissions from the memory system 110 to the host device 102). The DIN and DOUT lines may be two separate conductors, or the DIN and DOUT lines may include multiple conductors. In some embodiments, the DIN and DOUT lines may be asymmetric with the DIN line including N conductors and the DOUT line including M conductors, with N>M or M>N.

The UFS driver 330 may generate and decode packets to carry out transactions requested by the application 334. The packets are transmitted over the memory interface 310. The packets may be formatted as UFS Protocol Information Units (UPIUs). In a transaction with the memory system 110, the host device 102 is an initiator and the memory system 110 is a target. The UFS driver 330, based on the type of transaction, may form one of several types of UPIUs for handling SCSI commands, data operations, task management operations, and/or query operations. Each transaction may include one command UPIU, zero or more DATA IN or DATA OUT UPIUs, and a response UPIU. Each UPIU may include a header followed by optional fields depending on the type of UPIU.

One example transaction is a read operation. A read transaction may include the initiator (e.g., host device 102) transmitting a command UPIU for causing the target (e.g., memory system 110) to perform a read operation requested by the application 334. The target provides one or more DATA IN UPIUs in response to the command UPIU, in which the DATA IN UPIUs include the requested data. The read transaction is completed by the target transmitting a Response UPIU.

Another example transaction is a write operation. A write operation may include the initiator (e.g., host device 102) transmitting a command UPIU for causing the target (e.g., memory system 110) to perform a write operation requested by the application 334. The target provides a Ready to Transfer UPIU signaling the initiator to begin transfer of write data. The initiator then transmits one or more DATA OUT UPIUs, which are followed by a Ready to Transfer UPIU signaling the initiator to continue transfer of the write data. The sequence of DATA OUT UPIUs and Ready to Transfer UPIU continues until all write data is provided to the target, after which the target provides a Response UPIU to the initiator.

A further example transaction is a query operation. A query operation may include the initiator (e.g., host device 102) requesting information about the target (e.g., memory system 110). The initiator may transmit a Query Request UPIU to request information such as configuration, enumeration, device descriptor, flags, and/or attributes of the target. Example query operations includes read descriptor, write descriptor, read attribute, write attribute, read flag, set flag, clear flag, and/or toggle flag. Example descriptors include device, configuration, unit, interconnect, string, geometry, power, and/or device health. Example flags include fDeviceInit, fPermanenetWPEn, fPowerOn WPEn, fBackgroundOpsEn, fDeviceLifeSpanModeEn, fPurgeEnable, fRefreshEnable, fPhyResourceRemoval, fBusyRTC, and/or fPermanentlyDisableFwUpdate. Example attributes include bBootLunEn, bCurrentPowerMode, bActiveICCLevel, bOutOfORderDataEn, bBackgroundOpStatus, bPurgeStatus, bMaxDataInSize, bMaxDataOutSize, dDynCapNeeded, bRefClkFreq. Such flags may, for example, be flags identified by the UFS standard.

The operations and capabilities described above may be used for a memory system that supports detecting and tracking a quantity of errors in memory using a counter and indicating the detection and quantity of errors using an interrupt flag.

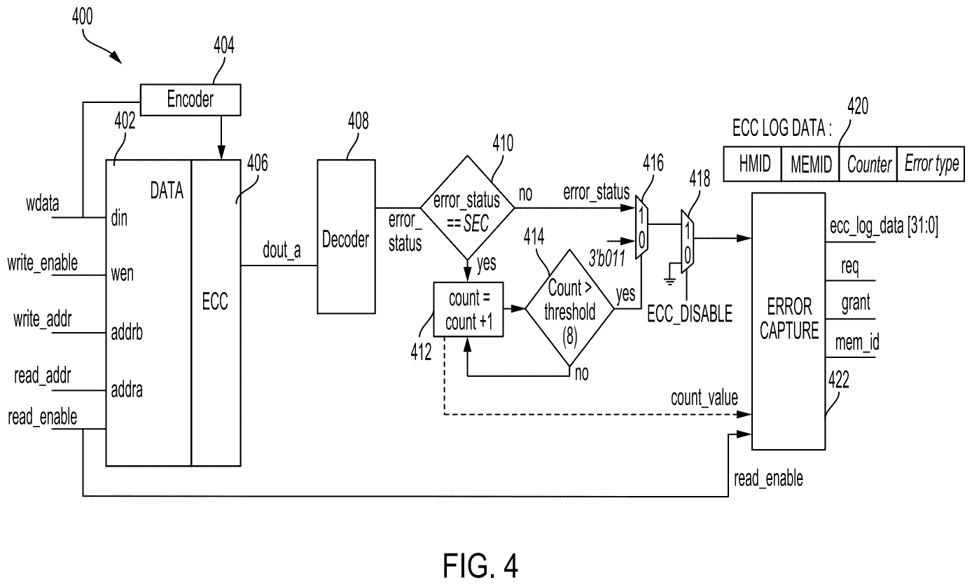

FIG. 4 is a flow diagram 400 illustrating a method for generating an ECC fault signature according to some embodiments of the disclosure. The flow diagrams described herein, including the flow diagram 400, may implement aspects of or may be implemented by aspects of the memory processing system 100. In the following descriptions of flow diagrams described herein, including the flow diagrams 700-1100 of FIGS. 7-11, respectively, the operations may be performed in different orders or at different times than the exemplary order shown. Some operations and/or components may also be omitted from the flow diagram, or other operations and/or components may be added to the flow diagram. The examples described herein are not to be construed as limiting, as the described features may be associated with any quantity of different devices.

Although the techniques described herein are described with respect to hardware and software on the same device or integrated circuit, additionally or alternatively, the hardware and software may be on different devices that communicate using an interface. For example, the software may be on a host device (e.g., host device 102) and the hardware may be part of the memory system 110 of FIG. 3.

In some examples, the system of generating the ECC fault signature indicated by the flow diagram 400 may be performed in hardware. The system may include a memory 402 that receives input data to be written into the memory 402 (wdata, wen) and a signal enabling the write operation (write_enable, wen), has an address specifying a memory location for writing (write_addr, addrb) and a memory location for reading (read_addr, addra), and receives a signal enabling the read operation (read_enable). The memory 402 may be associated with an ECC 406, for example, where the ECC is integrated in the memory 402, controlled by a memory controller, etc. An encoder 404 may process the input data to be written into memory 402 by transforming or adding additional information to the data, such as redundancy bits that the encoder 404 generates based on an ECC 406.

The ECC 406 may process the input data to be written to add extra or redundancy bits that enable error detection and correction. For example, the ECC 406 may encode the input data by adding the redundancy bits, often referred to as parity bits or check bits, to the original input data (wdata). The redundancy bits may allow errors that occur during storage in memory 402 to be detected and/or corrected when the data is read from memory. For example, the encoded data, which includes the original data (wdata) and the redundancy bits, may be written into the memory 402.

A decoder 408 may receive the encoded data (dout_a) and may analyze the encoded data to identify and errors that may have occurred during the data storage. For example, the decoder 408 may recalculate the redundancy bits based on the read data and compare to stored parity bits. If there is a mismatch between the recalculated parity bits and the stored parity bits, an error may be detected. For example, as previously discussed, an SEC error may be detected, indicating that the data is altered by a single bit, either from 0 to 1 or 1 to 0. The multiple-bit error is when two or more bits are altered in the data packet, such as a DED error that indicates that two or more bits are incorrect.

In some examples, the error detection may be performed at a GPU (e.g., hardware). At decision 410, the hardware may determine whether an error occurred (error_status from decoder). In particular, the hardware may determine whether a SEC error occurred since the SEC errors may be resolved by the software discussed herein to prevent a more significant error from occurring, such as a DED error that may likely occur after multiple single-bit errors occur.

If an SEC error has occurred, then a counter 412 may count the error. The counter 412 may continue incrementing the count based on subsequent SEC errors. At decision 414, the system may include determining whether the count of SEC errors has reached a threshold quantity of errors (e.g., SECs threshold for the particular memory 402). The counter 412 may continue to count the SEC errors until the threshold is reached. If the quantity of SEC errors has reached the threshold, then the hardware may send an indication (3′b011 code) of the error type and that the threshold has been reached (e.g., 1-bit error fault occurrence >threshold) to a multiplexer 416, along with the error status from decision 410 indicating that the error status is not a single-bit error. As an example, the following table may indicate the ECC statuses and corresponding type of errors.

TABLE 1
ECC Statuses and Corresponding Type of Error

| ECC_STATUS | Type of Error |
|---|---|
| 000 | No error |
| 001 | 1-bit error detected in data which is |
| | correctable; dout from decoder is |
| | corrected |
| 010 | 2-bit error detected; non-correctable |
| 100 | 1-bit error in check bits |
| 011 | 1-bit error fault occurrence > threshold |
| other | reserved |

The multiplexer 416 may output one of the two input received, such as the indication of the SEC error reaching the threshold (3′b011), which may be an input to multiplexer 418. The outputs of the multiplexer 418 may be an input to an ECC capture logger 422 or may result in disabling the ECC (ECC_disable). The count value from the counter 412 and the read enable signal may be inputs to the ECC capture logger 422. Accordingly, the ECC capture logger 422 may capture an indication of the error status from multiplexer 418, the count value from the counter 412, and may be enabled to read data (read_enable).

The ECC capture logger 422 (e.g., ECC logger) may include an ECC log data 420 to generate the ECC fault signature, which may include multiple bits field, such as 32 bits for logging and capturing data (ecc_log_data [31:0]). The error-related data of the ECC log data 420 may include a hardware module identifier (HMID) that indicates the hardware source of the error for the ECC fault signature. The ECC log data 420 may indicate a memory module identifier (MEMID) that indicates the particular memory where the error occurred (e.g., memory 402) for the ECC fault signature. The ECC log data 420 may include the count of errors (COUNTER (nbits)) and the error type (ECC_STATUS (3b)), as described in Table 1, for the ECC fault signature.

The ECC capture logger 422 may output the ecc_log_data (e.g., 32-bit signal including the ECC error-related information) for the ECC fault signature. The ECC capture logger 422 may output a request signal (req) indicating a request to a log, a grant signal indicating that the request is approved, and a memory identifier (mem_id) identifying the memory having errors.

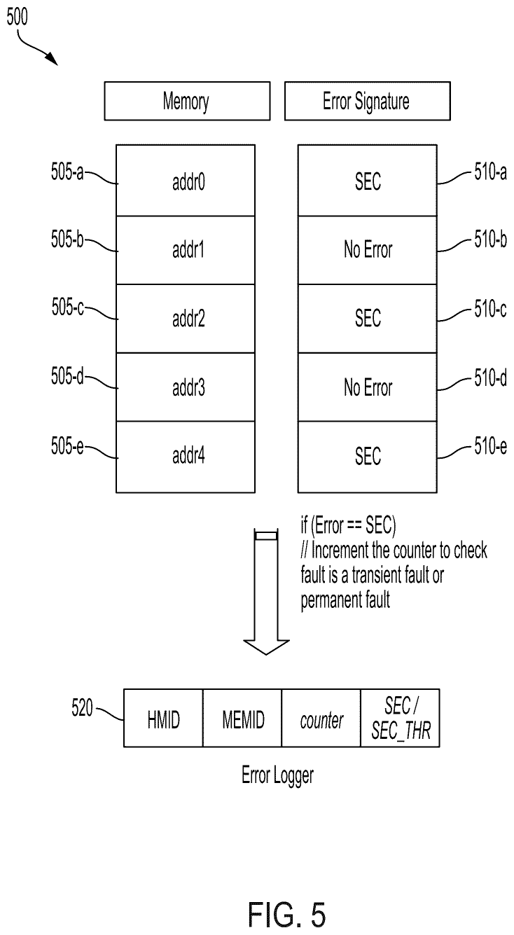

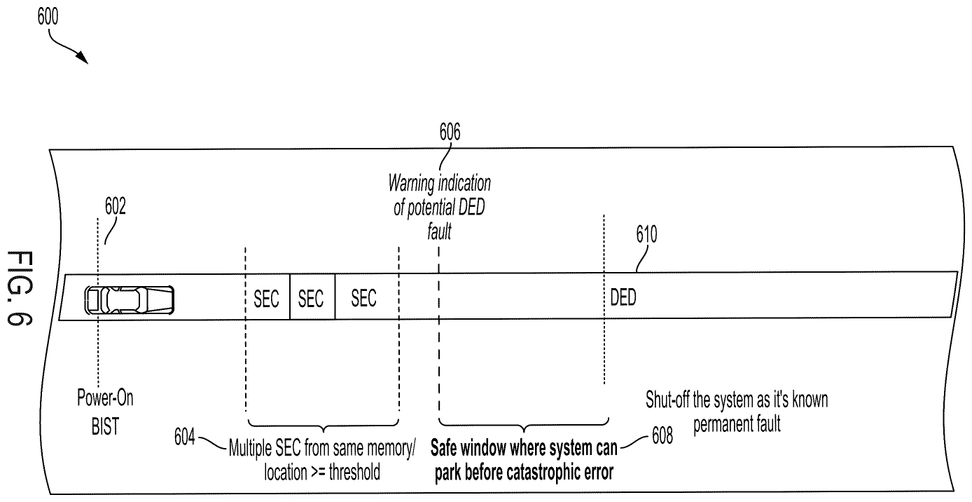

FIG. 5 is an example 500 of an error logging according to some embodiments of the disclosure. A memory may have multiple addresses 505, including a first address 505-a (addr0), a second address 505-b (addr1), a third address 505-c (addr2), a fourth address 505-d (addr3), and a fifth address 505-e (addr4). An SEC error may occur at some of the addresses 505 and the errors may be indicated in an ECC error signature (e.g., fault signature). For example, a first error signature 510-a associated with the first address 505-a, a third error signature 510-c associated with the third address 505-c, and a fifth error signature 510-e associated with the fifth address 505-e, may indicate that an SEC error occurred. A second error signature 510-b associated with the second address 505-b and a fourth error signature 510-d associated with the fourth address 505-d may indicate no errors have occurred. The counter for the memory may incrementally increase when the error is indicated in the error signature 510. Accordingly, the counter may increment when the error check occurs at the first address 505-a, the third address 505-c, and the fifth address 505-e. The counter may increment to check whether the error is a transient fault or a permanent fault. The transient fault may be a temporary error in the memory that does not indicate a permanent hardware failure. For example, the transient fault may be an SEC error. The permanent fault may be a persistent error that may result in shutting down the memory system, such as for a DED error. The quantity of SEC errors when the threshold has been reached (“counter”) and the error type (“SEC/SEC_THR”) indicating that the SEC errors reached the SEC threshold for the memory, may be captured by an error logger. The information may be stored in a ECC fault signature for the memory, which may provide logged information as described with respect to the ECC log data 420 of FIG. 4.

FIG. 6 is an example 600 illustrating usage of the detecting and tracking errors prior to processing according to some embodiments of the disclosure. For example, a hardware of a vehicle may perform a power-on built-in-self-test 602 (BIST). The hardware may perform the power-on BIST 602 diagnostic test to verify that the vehicle's internal components and systems are operating as expected.

Using the techniques described with respect to FIG. 4 and FIG. 5, the hardware may detect and track 604 multiple SEC errors occurring within the same memory of the vehicle. The detected and tracked quantity of SEC errors may be equal to or exceed the threshold quantity of single-bit errors for the memory. In some examples, multiple SEC errors may be followed by a permanent fault, such as a DED. A DED may cause the system to shut down.

For example, SECs may be detected and corrected but DEDs may be permanent errors that may not be correct and instead, be indicated to the software for subsequent shutting down of the system. Often, once a DED is detected, the system may be reset to identify whether the detected error is transient or permanent. A time frame or window between a detected DED to a shutdown of the system may result in unfavorable conditions for the vehicle. For example, during the window, the system may reset, identify permanent error associated with the DED, and then shut down the system.

Using the techniques described herein, the hardware may instead send a warning 606 indication (e.g., flag) of the potential DED fault (that may occur since the SECs reached or exceeded the threshold) to the software of the system. In this manner, the software may plan for the shutdown. For example, the warning 606 may result in a safe window 608, which may be time frame long enough for the vehicle to park (e.g., preemptive measures) before the DED occurs, resulting in the system shutting down.

Accordingly, after the safe window 608, the DED 610 may occur. That is, the DED 610 may occur in safe or favorable conditions for the system to shut down 612. Thus, using the techniques described herein, the SECs may be counted at the hardware, an indication of a potential DED (e.g., permanent error) may be provided to the software prior to the DED or may be inferred by the software based on the indication of the SECs reaching the threshold, so that the software may cause the vehicle to be in a safe condition or environment prior to the shutdown.

FIG. 7 is a flow diagram 700 illustrating a method for generating the ECC fault signature according to some embodiments of the disclosure. The hardware may detect an error status 702 at one or more addresses of a memory to generate the error type 718 for the ECC fault signature 720. The detected error status 702 may indicate a no error indication 704, a DED error indication 706, an SEC error indication 708, or a 1-bit check error indication 710, as described in Table 1 of FIG. 4 and as discussed herein.

For the SEC error indication 708, the hardware may determine at decision 712, via a counter, whether a quantity of SECs (e.g., single-bit errors) at one or more addresses of the memory exceeds a threshold quantity of SECs. The threshold may be set based on applications associated with the memory. As an example, the threshold may be set to 8 SECs (as shown) or another quantity of errors (e.g., 2, 5, 10, 12, and so forth). If the quantity of SECs exceeds the threshold, then a SEC error max indication 714 may be logged as an error type in an ECC fault signature 720. The error logging and recording may operate as discussed with respect to FIG. 4 and FIG. 5. The error type may be indicated by a set of bits, such as 3 bits, indicative of the type of error. For example, the bits may be 011 (e.g., new type of error value). The SEC error max indication 714 may be indicated as “SEC error_max=3′b011.” However, if the quantity of SECs does not exceed the threshold, then an SEC indication 716 may be logged as the error type in the ECC fault signature 720. The SEC indication 716 may be indicated as “SEC=3′b011.”

In some examples, the ECC fault signature 720 may include 8 bits for the HMID, 8 bits for the MEM ID, 2 bits for the Count (e.g., quantity of SECs), and 3 bits for the error type. That is, the ECC fault signature 720 may have a format including bits to indicate the quantity of SEC errors that occurred at the same memory along with the error type value rather than a fault signature indicating a single address (for location of the error) along with the error type. For example, the techniques discussed herein may replace the read address in the ECC fault signature 720 with the quantity of SECs, as well as provide a new value for the error type 718, such as the 011 ECC status that indicates an error type of 1-bit error fault occurrence reaching or exceeding the threshold. The ECC fault signature 720 indicating the count of SECs and the new error type may facilitate efficient remedial actins performed by the software and reduce latencies otherwise associated with the software retrieving the ECC fault signature for each occurrence of an error. The software may efficiently identify that the quantity of SECs has reached a threshold and thus, a DED error may occur in an upcoming error, and take preemptive measures accordingly.

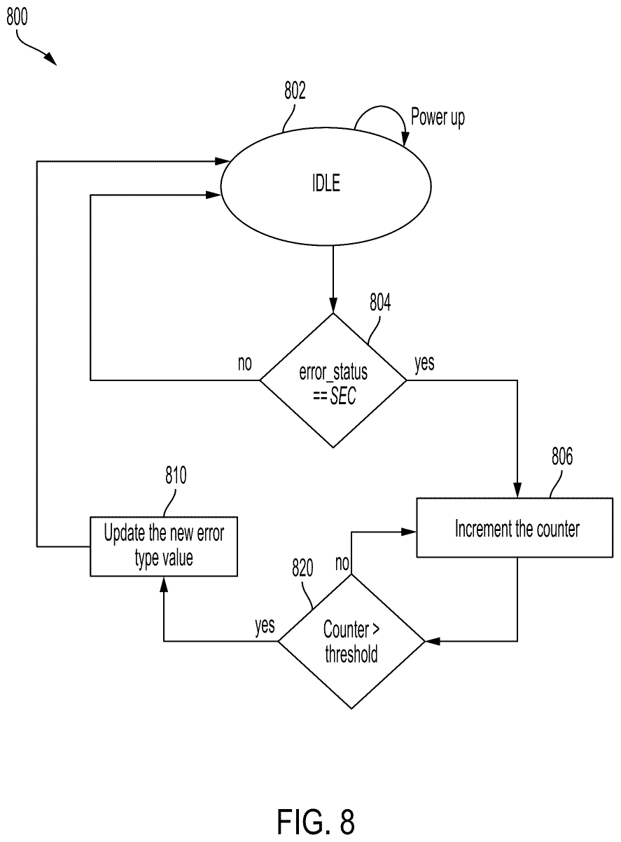

FIG. 8 is a flow diagram 800 illustrating a method for counting errors at a counter according to some embodiments of the disclosure. Counting errors may be performed using a finite state machine (FSM), for example, for incrementing the counter value. During a power up state, the FSM may be in an idle state 802. The hardware may check 804 the error status, such as from a decoder (e.g., decoder 408 of FIG. 4). For example, the hardware may determine whether the error status indicates an SEC error. If the error status does not indicate an SEC error, the hardware may continue checking the error status from the decoder. If the error status indicates an SEC error, then the hardware may increment 806 a counter. The counter may continue to increment and the counter may determine at decision 820, whether the count of SECs is equal to or exceeds a threshold. If the quantity is below the threshold, then the hardware may continue to increment 806 the counter. If the quantity is equal to or greater than the threshold, the hardware may update 810 the error type with the new error type value (e.g., 011) and return to the idle state 802. The error type value of 011 may indicate a 1-bit error fault occurrence is equal to or greater than a threshold, as discussed herein.

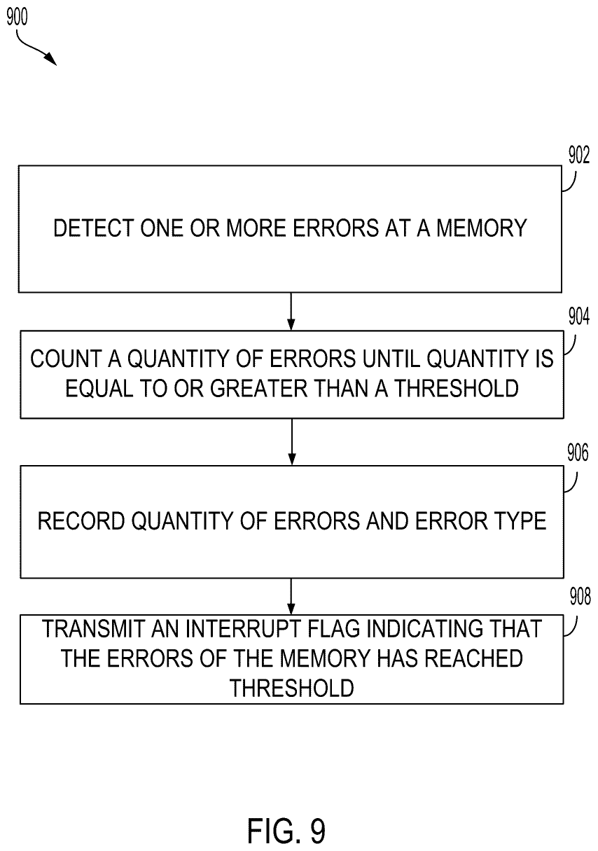

FIG. 9 is flow chart illustrating a method 900 for detecting and tracking errors of a memory system according to some embodiments of the disclosure. The method 900 may implement aspects of or may be implemented by aspects of the memory processing system 100, the host device 102, and/or the memory system 110. As an example, the method 900 may be performed by hardware of the memory system 110, as discussed herein. Additionally, or alternatively, the method may be performed by hardware of the host device 102 (e.g., hardware and software are on separate devices or chips). In the following description of the method 900, the operations performed by the hardware may be performed in different orders or at different times than the exemplary order shown. Some operations may also be omitted from the method 900, or other operations may be added to the method 900. Further, while operations in the method 900 are illustrated and described as being performed by the hardware and (of the memory system), the examples herein are not to be construed as limiting, as the described features may be associated with any quantity of different device.

At step 902, the hardware of a memory system may detect one or more errors (e.g., SEC errors) at a memory. The one or more errors may be associated with one or more addresses of the memory. The one or more errors may include SEC errors.

At step 904, the hardware may count a quantity of the one or more errors until the quantity is equal to or greater than a threshold quantity of errors for the memory. In some examples, the hardware may include a counter. The hardware may increment the counter based on a detection of an error of the one or more errors. In particular, the hardware may determine a total number of errors as the quantity of the one or more errors based on errors counted at various addresses of the memory. For example, an error detected at a first memory address of the memory and an error detected at a second memory address of the memory may result in detecting or counting two errors in total for the memory.

At 906, the hardware may record (e.g., via the ECC capture logger) the quantity of errors and associated error type (e.g., 011, SECs reaching threshold) in an error log (e.g., ECC fault signature).

At 908, the hardware may transmit an indication the quantity of errors of the memory is equal to or greater than the threshold. In some examples, the indication may be an interrupt flag that indicates the type of error of the quantity of errors reaching the threshold. In some examples, the indication that the quantity of errors is equal to or greater than the threshold is a set of bits indicative of the error type. In some examples, the indication that the quantity errors is equal to or greater than the threshold indicates an expectation of a DED error. In some examples, the hardware may transmit the indication to a software of the memory system. In some examples, the hardware may be a GPU associated with the memory (e.g., GPU of the memory system).

In some examples, the hardware may be in a vehicle and the hardware may transmit a notification (e.g., to a user on a user interface of the vehicle). The notification may be to discontinue use of the vehicle (e.g., park the vehicle prior to shutting down the vehicle, safety mechanism) based on the indication of the quantity of errors of the memory being equal to or greater than the threshold, as discussed with respect to FIG. 6.

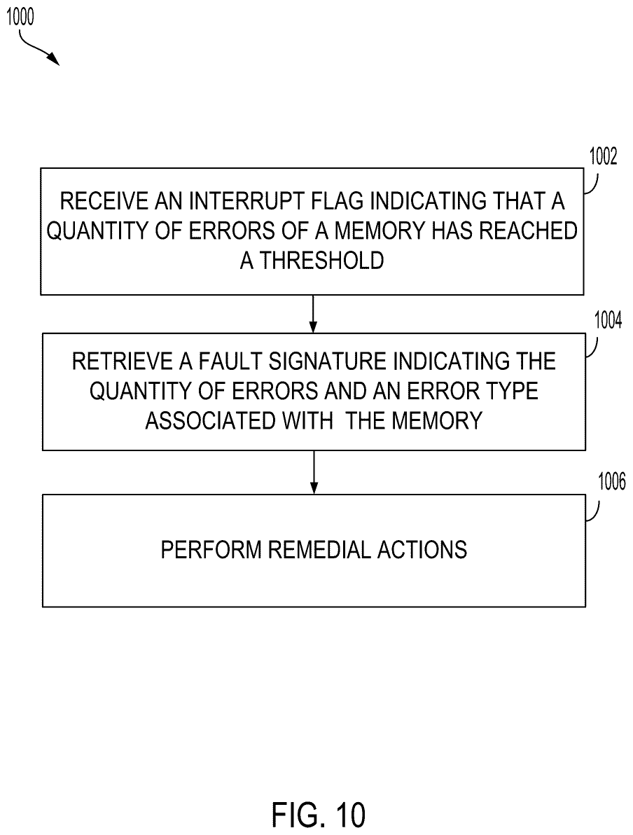

FIG. 10 is a flow chart illustrating a method 1000 for resolving for errors by software of a memory system according to some embodiments of the disclosure. The method 1000 may implement aspects of or may be implemented by aspects of the memory processing system 100, the host device 102, and/or the memory system 110. As an example, the method 1000 may be performed by software of the memory system 110, as discussed herein. Additionally, or alternatively, the method 1000 may be performed by software of the host device 102 (e.g., hardware and software are on separate devices or chips). In the following description of the method 1000, the operations performed by the software may be performed in different orders or at different times than the exemplary order shown. Some operations may also be omitted from the method 1000, or other operations may be added to the method 1000. Further, while operations in the method 1000 are illustrated and described as being performed by the software and (of the memory system), the examples herein are not to be construed as limiting, as the described features may be associated with any quantity of different device.

At step 1002, the software may receive an interrupt flag indicating that a quantity of errors of a memory has reached a threshold. For example, the software may be occupied in processing or performing tasks, and the interrupt flag may trigger the software to switch to retrieving the ECC fault signature associated with the interrupt flag. The interrupt flag may indicate that a particular memory has reached or exceeded the threshold limit of SEC errors. The interrupt flag may indicate a new ECC status, 011, which is indicative of a single-bit error fault occurrence that has reached or exceeded a threshold. Thus, the software may be aware, based on the ECC status code, that a particular memory has failed due to the SECs reaching or exceeding the threshold. The fault of the SECs reaching or exceeding the threshold may lead to a DED error occurring, and thus, based on the 011 ECC status, the software may take preemptive measures for a possible DED error.

At step 1004, the software may retrieve an ECC fault signature that indicates a count of the SEC errors and the error type, as discussed in detail with respect to FIGS. 4-9. At step 1006, the software make perform remedial actions. For example, the software may take preemptive measures that may be impacted by a DED error that often occurs after the SECs reach or exceed the threshold.

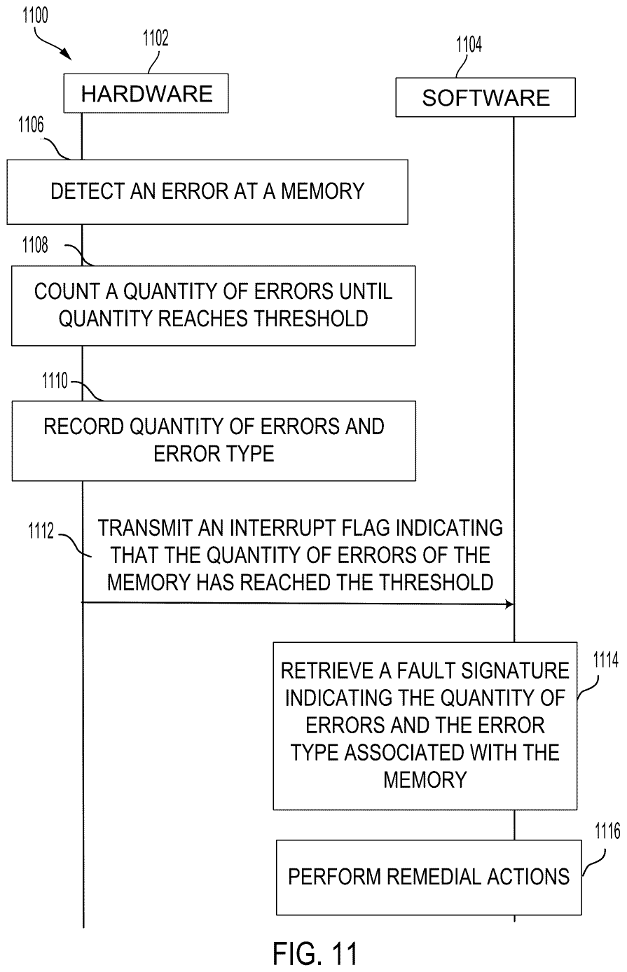

FIG. 11 is a flow chart illustrating a method 1100 for resolving errors occurring at a memory using hardware and software according to some embodiments of the disclosure. The method 1100 briefly describes the steps performed by the hardware described with respect to FIG. 9 and the steps performed by the software described with respect to FIG. 10. For example, the method 1100 summarizes the communication between the hardware and the software when performing the steps that are described in detail in FIG. 9 and FIG. 10, respectively.

The method 1100 may implement aspects of or may be implemented by aspects of the memory processing system 100, the host device 102, and/or the memory system 110. As an example, the method 1100 may be performed by software and hardware of the memory system 110, as discussed herein. Additionally, or alternatively, the method 1100 may be performed by software of the host device 102 and hardware of the memory system 110. In the following description of the method 1100, the operations performed by the hardware or software may be performed in different orders or at different times than the exemplary order shown. Some operations may also be omitted from the method 1100, or other operations may be added to the method 1100. Further, while operations in the method 1100 are illustrated and described as being performed by the software or hardware, the examples herein are not to be construed as limiting, as the described features may be associated with any quantity of different device.

At step 1106, the hardware may detect an error at a memory, as described with respect to FIG. 9. At step 1108, the hardware may count a quantity of errors (e.g., SEC errors) until the quantity reaches (e.g., is equal to or exceeds) a threshold quantity of errors associated with the memory, as described with respect to FIG. 9. At step 1110, the hardware 1102 may log the quantity of errors and the error type, as described with respect to FIG. 9. At step 1112, the hardware 1102 may transmit an interrupt flag indicating that a quantity of errors of a memory has reached the threshold, as described with respect to FIG. 9.

At step 1114, the software 1104 may retrieve a fault signature indicating the quantity of errors and the error type associated with the memory, as described with respect to FIG. 10. At step 1116, the software 1104 may perform remedial actions, as described with respect to FIG. 10.

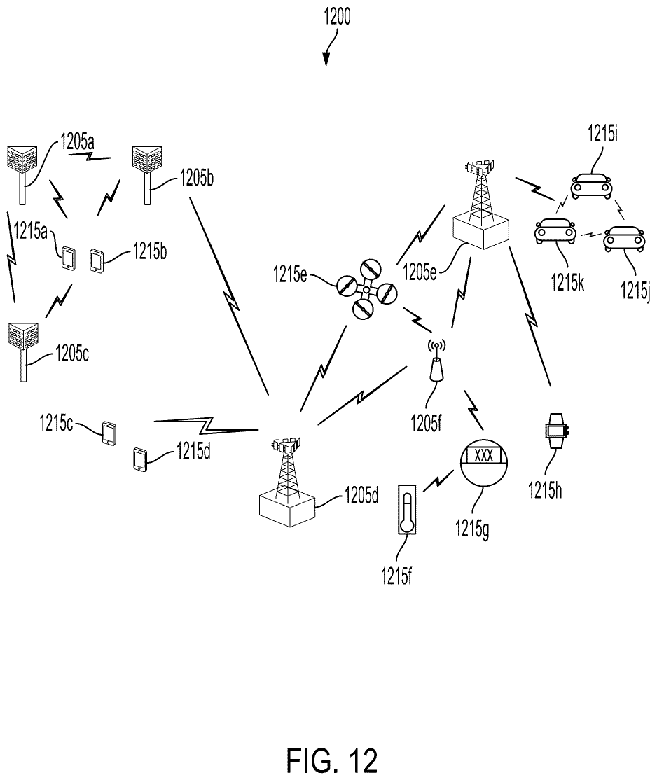

FIG. 12 is a block diagram illustrating details of an example wireless communication system according to one or more aspects. The wireless communication system may include wireless network 1200. Wireless network 1200 may, for example, include a 5G wireless network. As appreciated by those skilled in the art, components appearing in FIG. 12 are likely to have related counterparts in other network arrangements including, for example, cellular-style network arrangements and non-cellular-style-network arrangements (e.g., device to device or peer to peer or ad hoc network arrangements, etc.).

Wireless network 1200 illustrated in FIG. 12 includes a number of base stations 1205 and other network entities. A base station may be a station that communicates with the UEs and may also be referred to as an evolved node B (eNB), a next generation eNB (gNB), an access point, and the like. Each base station 1205 may provide communication coverage for a particular geographic area. In 3GPP, the term “cell” may refer to this particular geographic coverage area of a base station or a base station subsystem serving the coverage area, depending on the context in which the term is used. In implementations of wireless network 1200 herein, base stations 1205 may be associated with a same operator or different operators (e.g., wireless network 1200 may include a plurality of operator wireless networks). Additionally, in implementations of wireless network 1200 herein, base station 1205 may provide wireless communications using one or more of the same frequencies (e.g., one or more frequency bands in licensed spectrum, unlicensed spectrum, or a combination thereof) as a neighboring cell. In some examples, an individual base station 1205 or UE 1215 may be operated by more than one network operating entity. In some other examples, each base station 1205 and UE 1215 may be operated by a single network operating entity.

A base station may provide communication coverage for a macro cell or a small cell, such as a pico cell or a femto cell, or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A base station for a macro cell may be referred to as a macro base station. A base station for a small cell may be referred to as a small cell base station, a pico base station, a femto base station or a home base station. In the example shown in FIG. 12, base stations 1205d and 1205e are regular macro base stations, while base stations 1205a-1205c are macro base stations enabled with one of 3 dimension (3D), full dimension (FD), or massive MIMO. Base stations 1205a-1205c take advantage of their higher dimension MIMO capabilities to exploit 3D beamforming in both elevation and azimuth beamforming to increase coverage and capacity. Base station 1205f is a small cell base station which may be a home node or portable access point. A base station may support one or multiple (e.g., two, three, four, and the like) cells.

Wireless network 1200 may support synchronous or asynchronous operation. For synchronous operation, the base stations may have similar frame timing, and transmissions from different base stations may be approximately aligned in time. For asynchronous operation, the base stations may have different frame timing, and transmissions from different base stations may not be aligned in time. In some scenarios, networks may be enabled or configured to handle dynamic switching between synchronous or asynchronous operations.

UEs 1215 are dispersed throughout the wireless network 1200, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, a gaming device, an augmented reality device, vehicular component, vehicular device, or vehicular module, or some other suitable terminology. Within the present document, a “mobile” apparatus or UE need not necessarily have a capability to move, and may be stationary. Some non-limiting examples of a mobile apparatus, such as may include implementations of one or more of UEs 1215, include a mobile, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A mobile apparatus may additionally be an IoT or “Internet of everything” (IoE) device such as an automotive or other transportation vehicle, a satellite radio, a global positioning system (GPS) device, a global navigation satellite system (GNSS) device, a logistics controller, a flying device, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, gesture tracking device, medical device, a digital audio player (e.g., MP3 player), a camera, a game console, etc.; and digital home or smart home devices such as a home audio, video, and multimedia device, an appliance, a sensor, a vending machine, intelligent lighting, a home security system, a smart meter, etc. In one aspect, a UE may be a device that includes a Universal Integrated Circuit Card (UICC). In another aspect, a UE may be a device that does not include a UICC. In some aspects, UEs that do not include UICCs may also be referred to as IoE devices. UEs 1215a-1215d of the implementation illustrated in FIG. 12 are examples of mobile smart phone-type devices accessing wireless network 1200. A UE may also be a machine specifically configured for connected communication, including machine type communication (MTC), enhanced MTC (eMTC), narrowband IoT (NB-IOT) and the like. UEs 1215e-1215k illustrated in FIG. 12 are examples of various machines configured for communication that access wireless network 1200.

A mobile apparatus, such as UEs 1215, may be able to communicate with any type of the base stations, whether macro base stations, pico base stations, femto base stations, relays, and the like. In FIG. 12, a communication link (represented as a lightning bolt) indicates wireless transmissions between a UE and a serving base station, which is a base station designated to serve the UE on the downlink or uplink, or desired transmission between base stations, and backhaul transmissions between base stations. UEs may operate as base stations or other network nodes in some scenarios. Backhaul communication between base stations of wireless network 1200 may occur using wired or wireless communication links.

In operation at wireless network 1200, base stations 1205a-1205c serve UEs 1215a and 1215b using 3D beamforming and coordinated spatial techniques, such as coordinated multipoint (CoMP) or multi-connectivity. Macro base station 1205d performs backhaul communications with base stations 1205a-1205c, as well as small cell, base station 1205f. Macro base station 1205d also transmits multicast services which are subscribed to and received by UEs 1215c and 1215d. Such multicast services may include mobile television or stream video, or may include other services for providing community information, such as weather emergencies or alerts, such as Amber alerts or gray alerts.

Wireless network 1200 of implementations supports mission critical communications with ultra-reliable and redundant links for mission critical devices, such UE 1215e, which is an aeronautical vehicle. Redundant communication links with UE 1215e include from macro base stations 1205d and 1205e, as well as small cell base station 1205f. Other machine type devices, such as UE 1215f (thermometer), UE 1215g (smart meter), and UE 1215h (wearable device) may communicate through wireless network 1200 either directly with base stations, such as small cell base station 1205f, and macro base station 1205e, or in multi-hop configurations by communicating with another user device which relays its information to the network, such as UE 1215f communicating temperature measurement information to the smart meter, UE 1215g, which is then reported to the network through small cell base station 1205f. Wireless network 1200 may also provide additional network efficiency through dynamic, low-latency TDD communications or low-latency FDD communications, such as in a vehicle-to-vehicle (V2V) mesh network between UEs 1215i-1215k communicating with macro base station 1205e.

In various implementations, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, GSM networks, 5th Generation (5G) or new radio (NR) networks (sometimes referred to as “5G NR” networks, systems, or devices), as well as other communications networks. As described herein, the terms “networks” and “systems” may be used interchangeably. A CDMA network, for example, may implement a radio technology such as universal terrestrial radio access (UTRA), cdma2000, and the like. UTRA includes wideband-CDMA (W-CDMA) and low chip rate (LCR). CDMA2000 covers IS-2000, IS-95, and IS-856 standards. A TDMA network may, for example implement a radio technology such as Global System for Mobile Communication (GSM). The 3rd Generation Partnership Project (3GPP) defines standards for the GSM EDGE (enhanced data rates for GSM evolution) radio access network (RAN), also denoted as GERAN. An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long-term evolution (LTE) is a release of UMTS that uses E-UTRA. The various different network types may use different radio access technologies (RATs) and RANs.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, implementations or uses may come about via integrated chip implementations or other non-module-component based devices (e.g., end-user devices, vehicles, communication devices, computing devices, industrial equipment, retail devices or purchasing devices, medical devices, AI-enabled devices, etc.). While some examples may or may not be specifically directed to use cases or applications, a wide assortment of applicability of described innovations may occur. Implementations may range from chip-level or modular components to non-modular, non-chip-level implementations and further to aggregated, distributed, or original equipment manufacturer (OEM) devices or systems incorporating one or more described aspects. In some practical settings, devices incorporating described aspects and features may also necessarily include additional components and features for implementation and practice of claimed and described aspects. It is intended that innovations described herein may be practiced in a wide variety of implementations, including both large devices or small devices, chip-level components, multi-component systems (e.g., radio frequency (RF)-chain, communication interface, processor), distributed arrangements, end-user devices, etc. of varying sizes, shapes, and constitution.

In one or more aspects, techniques for detecting and tracking errors (e.g., faults) in a memory, may include additional aspects, such as any single aspect or any combination of aspects described below or in connection with one or more other processes or devices described elsewhere herein. In a first aspect, an electronic device, such as a vehicle, may be an apparatus that includes one or more memories storing processor-executable code and one or more processors coupled with the one or more memories. The one or more processors may be individually or collectively operable to execute the code to cause the apparatus to detect one or more errors at a memory. The one or more processors may be individually or collectively further operable to execute the code to cause the apparatus to count a quantity of the one or more errors until the quantity is equal to or greater than a threshold quantity of errors. The one or more processors may be individually or collectively further operable to execute the code to cause the apparatus to record the quantity of errors and an error type in an error log. The one or more processors may be individually or collectively further operable to execute the code to cause the apparatus to transmit an indication of the quantity of errors of the memory being equal to or greater than the threshold.

In some examples, the apparatus may include a counter. The one or more processors may be individually or collectively further operable to execute the code to cause the apparatus to increment the counter based on a detection of an error of the one or more errors. In some examples, the one or more errors may be associated with one or more addresses of the memory. In some examples, the indication may include an interrupt flag. In some examples, to transmit the indication, the one or more processors may be individually or collectively further operable to execute the code to cause the apparatus to transmit the indication to a software of a memory system associated with the memory, and where the apparatus include a hardware associated with the memory.

In such examples, the hardware may include a graphical processing unit associated with the memory. In some examples, the indication that the quantity of errors is equal to or greater than the threshold may include a set of bits indicative of the error type. In some examples, the error type may be a single-bit error. In some examples, the indication that the quantity errors is equal to or greater than the threshold may indicate an expectation of a double-error detection error. In some examples, the apparatus includes a vehicle or may be associated with a vehicle, and the one or more processors may be individually or collectively further operable to execute the code to cause the apparatus to transmit a notification to discontinue use of the vehicle based at least in part on the indication of the quantity of errors of the memory being equal to or greater than the threshold.

In some examples, to count a quantity of the one or more errors, the one or more processors may be individually or collectively further operable to execute the code to cause the apparatus to determine a total number of errors as the quantity of the one or more errors based on at least in part on errors counted at a plurality of addresses of the memory.

In another aspect of the disclosure, a method for performing these operations by a processor by executing instructions stored in a memory coupled to the processor is also disclosed. In an additional aspect of the disclosure, a non-transitory computer-readable medium stores instructions that, when executed by a processor, cause the processor to perform these operations.

The memory system may include a memory controller coupled to a memory system through a first channel and configured to access data stored in the memory system through the first channel and coupled to a host device through a first interface and configured to communicate with the host device over the first interface. The operations may be executed as part of an initialization operation, a read operation or a write operation.

In a first aspect, the memory controller of the memory system may be configured to perform operations including detecting one or more errors at a memory. The operations may include counting a quantity of the one or more errors until the quantity is equal to or greater than a threshold quantity of errors. The operations may include recording the quantity of errors and an error type in an error log. The operations may include transmitting an indication of the quantity of errors of the memory being equal to or greater than the threshold.

In a second aspect, in combination with the first aspect, the memory system may include a counter. The operations may include incrementing the counter based on a detection of an error of the one or more errors.

In a third aspect, in combination with one or more of the first aspect or the second aspect, the one or more errors are associated with one or more addresses of the memory.

In a fourth aspect, in combination with one or more of the first aspect through the third aspect, the indication may include an interrupt flag.

In a fifth aspect, in combination with one or more of the first aspect through the fourth aspect, the operations for transmitting the indication may include transmitting the indication to a software of a memory system associated with the memory, and where the apparatus includes a hardware associated with the memory.

In a sixth aspect, in combination with one or more of the first aspect through the fifth aspect, the hardware may include a GPU associated with the memory.

In a seventh aspect, in combination with one or more of the first aspect through the sixth aspect, the indication that the quantity of errors is equal to or greater than the threshold may include a set of bits indicative of the error type.

In an eighth aspect, in combination with one or more of the first aspect through the seventh aspect, the error type may be a single-bit error.

In a ninth aspect, in combination with one or more of the first aspect through the eighth aspect, the indication that the quantity errors is equal to or greater than the threshold may indicate an expectation of a double-error detection error.

In a tenth aspect, in combination with one or more of the first aspect through the ninth aspect, the apparatus may be a vehicle and the operations may include transmitting a notification to discontinue use of the vehicle based at least in part on the indication of the quantity of errors of the memory being equal to or greater than the threshold.

In an eleventh aspect, in combination with one or more of the first aspect through the tenth aspect, the operations may include determining a total number of errors as the quantity of the one or more errors based at least in part on errors counted at a plurality of addresses of the memory.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-11 include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

Those of skill in the art that one or more blocks (or operations) described with reference to FIGS. 4-11 may be combined with one or more blocks (or operations) described with reference to another of the figures. For example, one or more blocks (or operations) of FIG. 1 may be combined with one or more blocks (or operations) of FIG. 3. As another example, one or more blocks associated with FIG. 1 may be combined with one or more blocks (or operations) associated with FIGS. 4-11. Additionally, or alternatively, one or more operations described above with reference to FIGS. 1-3 may be combined with one or more operations described with reference to FIGS. 4-11.

Those of skill in the art would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, or, any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, opposing terms such as “upper” and “lower” or “front” and back” or “top” and “bottom” or “forward” and “backward” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus, comprising:
one or more memories storing processor-executable code; and
one or more processors coupled with the one or more memories and individually or collectively operable to execute the code to cause the apparatus to:
detect one or more errors at a memory;
count a quantity of the one or more errors until the quantity is equal to or greater than a threshold quantity of errors;
record the quantity of errors and an error type in an error log; and
transmit an indication of the quantity of errors of the memory being equal to or greater than the threshold quantity of errors.

2. The apparatus of claim 1, comprising:
a counter, wherein the one or more processors are individually or collectively further operable to execute the code to cause the apparatus to:
increment the counter based on a detection of an error of the one or more errors.

3. The apparatus of claim 1, wherein the one or more errors are associated with one or more addresses of the memory.

4. The apparatus of claim 1, wherein the indication comprises an interrupt flag.

5. The apparatus of claim 1, wherein, to transmit the indication, the one or more processors are individually or collectively further operable to execute the code to cause the apparatus to:
transmit the indication to a software of a memory system associated with the memory, and wherein the apparatus comprises a hardware associated with the memory.

6. The apparatus of claim 5, wherein the hardware comprises a graphical processing unit associated with the memory.

7. The apparatus of claim 1, wherein the indication that the quantity of errors is equal to or greater than the threshold quantity of errors comprises a set of bits indicative of the error type.

8. The apparatus of claim 1, wherein the error type is a single-bit error.

9. The apparatus of claim 1, wherein the indication that the quantity of errors is equal to or greater than the threshold quantity of errors indicates an expectation of a double-error detection error.

10. The apparatus of claim 1, wherein the apparatus comprises a vehicle and the one or more processors are individually or collectively further operable to execute the code to cause the apparatus to:
transmit a notification to discontinue use of the vehicle based at least in part on the indication of the quantity of errors of the memory being equal to or greater than the threshold quantity of errors.

11. The apparatus of claim 1, wherein, to count a quantity of the one or more errors, the one or more processors are individually or collectively further operable to execute the code to cause the apparatus to:
determine a total number of errors as the quantity of the one or more errors based at least in part on errors counted at a plurality of addresses of the memory.

12. A method, comprising:
detecting one or more errors at a memory;
counting a quantity of the one or more errors until the quantity is equal to or greater than a threshold quantity of errors;
recording the quantity of errors and an error type in an error log; and
transmitting an indication of the quantity of errors of the memory being equal to or greater than the threshold quantity of errors.

13. The method of claim 12, comprising:
incrementing a counter based on a detection of an error of the one or more errors.

14. The method of claim 12, wherein the one or more errors are associated with one or more addresses of the memory.

15. The method of claim 12, wherein the indication comprises an interrupt flag.

16. The method of claim 12, wherein transmitting the indication comprises:
transmitting the indication to a software of a memory system associated with the memory, and wherein a hardware of the memory system counts the quantity of the one or more errors.

17. The method of claim 16, wherein the hardware comprises a graphical processing unit associated with the memory.

18. The method of claim 12, wherein the indication that the quantity of errors is equal to or greater than the threshold quantity of errors comprises a set of bits indicative of the error type.

19. A non-transitory computer-readable medium storing code for wireless communications, the code comprising instructions executable by one or more processors to:
detect one or more errors at a memory;
count a quantity of the one or more errors until the quantity is equal to or greater than a threshold quantity of errors;
record the quantity of errors and an error type in an error log; and
transmit an indication of the quantity of errors of the memory being equal to or greater than the threshold quantity of errors.

20. The non-transitory computer-readable medium of claim 19, wherein the instructions are further executable by the one or more processors to:
increment a counter based on a detection of an error of the one or more errors at a plurality of memory addresses of the memory.
